(19) United States
(12) Patent Application Publication
(10) Pub. No.: US 2009/0133628 A1
(43) Pub. Date: May 28, 2009

(54) VACUUM DEVICE FOR CONTINUOUS PROCESSING OF SUBSTRATES

(75) Inventors: Roland DAHL, Dettingen (DE); Josef Haase, Griesingen (DE); Moritz Heintze, Ulm (DE); Thomas Pernau, Blaubeuren-Weiler (DE); Hans Reichart, Blaubeuren (DE); Harald Wanka, Blaustein (DE); Jan-Dirk Kaehler, Wedemark (DE); Reinhard Lenz, Blaubeuren (DE); Dieter Zernickel, Amstetten (DE); Robert Michael Hartung, Blaubeuren (DE)

Correspondence Address: HESLIN ROTHENBERG FARLEY & MESITI PC, 5 COLUMBIA CIRCLE, ALBANY, NY, 12203, US

(73) Assignee: Centrotherm Photovoltaics AG, Blaubeuren (DE)

(21) Appl. No.: 12/255,750

(22) Filed: Oct. 22, 2008

(30) Foreign Application Priority Data
Oct. 22, 2007 (DE) 10 2007 050 699.8
Apr. 15, 2008 (DE) 102008019023.3-45

(51) Int. Cl. C23C 16/54

(52) U.S. Cl. 118/718

(57) ABSTRACT

A continuous vacuum system for processing substrates has an inlet air lock, an outlet air lock, at least one process chamber, and a device for conveying the substrates through the continuous system. To create a continuous system having a compact design and high throughput for plasma-enhanced treatment of substrates at a reduced pressure, which ensures a simple, rapid and secure handling of the substrates with a high capacity of the substrate carrier, the conveying device has at least one plasma boat in which the substrates are arranged on a base plate in a three-dimensional stack in at least one plane at a predefined distance from one another with intermediate carriers in between. At least the intermediate carriers are made of graphite or another suitable electrically conductive material and can be acted upon electrically with an alternating voltage via an electric connection.

The invention relates to a continuous vacuum system for processing of substrates, having an inlet air lock and outlet air lock, at least one process chamber and a device for conveying the substrates through the continuous system.

The market demands production systems that meet the requirements of integration into manufacturing lines. This means, among other things, that the efficiency of the production system must be synchronized with the efficiency of the manufacturing line. The production system must first match the throughput of the manufacturing line. Since many different throughputs are customary in manufacturing lines on the market, a system concept, which allows different throughputs, must be available and must be designed so that the compactness of the system is retained for all throughputs and the system cost per unit of throughput remains constant for all throughput variants.

To maximize the throughput of a continuous vacuum system, in addition to the actual process time, the dead time, i.e., the time required for conveyance, opening and closing of the vacuum slide valves, etc., must be minimized. After optimizing these dead times, the throughout may be increased only by increasing the capacity of the substrate carrier.

One problem with the conventional continuous systems is the small and/or limited capacity of the substrate carrier. Despite the large design of a substrate carrier according to the state of the art (approximately 1 to 1.5 m wide and up to 1.8 m long), the capacity for conventional substrates of the size 156×156 mm is actually rather low, amounting to approximately 80 units.

Large-area substrate carriers require a large and therefore expensive vacuum system for processing at a low pressure. The complexity for passing the substrate carriers into and out of the air locks in particular increases with their size, so there is a limit to the throughput achievable at a justifiable expense.

For a throughput of more than 3,000 substrates per hour, continuous systems with flat substrate carriers require a system size that cannot be integrated well into manufacturing lines and also require a disproportionately great complexity in loading and unloading as well as in maintenance.

A large-area substrate carrier also leads to problems in loading because, for some substrates, the distance from receiving the substrate to depositing it on the substrate carrier is very great. Furthermore, for manual loading, the central substrate positions on the substrate carrier are very difficult for the operating personnel to reach during manual loading. The difficulty in loading ultimately results in an increased breakage rate.

For anti-reflective coating of solar cells, flat/planar substrate carriers are generally used in the state of the art; with these carriers, the substrates are arranged in rows and columns in one plane. A typical substrate carrier has a size of 1.0×1.8 m with a thickness of approximately 1 cm. The reactive plasma does not burn directly above or next to the substrates, so there is a loss of plasma-activated reactants on the route between the plasma and substrate.

Continuous systems for anti-reflective coating of solar cells in which planar substrate carriers are likewise used, are also known, whereby the substrates may be arranged in rows and columns in one plane. A typical substrate carrier has a size of 1.2×1.6 m with a thickness of approximately 1 cm.

In the continuous remote plasma systems according to the state of the art, flat substrate carriers are thus run through the system with the substrates arranged in a plane in a two-dimensional manner.

DE 199 62 896 describes a device for manufacturing solar cells according to a combined remote plasma/LPCVD method. This device has an elongated process tube made of quartz glass, which is provided with antechambers at the input and output ends that are large enough to each pass a wafer carrier made of quartz and having a plurality of upright silicon wafers through the air locks. Here, the wafers stand vertically, which allows a definite space-saving effect and/or an increase in productivity of the system. The required process steps (entry through inlet air lock, substrate heating, preplasma, coating, cooling, etc.) then take place one after the other at different positions in the process channel, wherein the quartz wafer carriers are conveyed step by step through the process channel. However, these wafer carriers are comparatively small and are not suitable for operation by the direct plasma technique, which requires a plasma discharge directly above the substrate surface.

Direct plasma CVD systems are provided for processing wafers in electrically conductive wafer carriers in the form of plasma boats, which allow a direct plasma discharge above the wafer surface. The plasma boats are processed in a batch operation, i.e., the process chamber has only a single main opening through which the plasma boats are introduced as well as removed.

Under reduced pressure (usually 0.5 to 5 mbar) and elevated temperature (usually 300-600° C.), the plasma boat is exposed to an atmosphere of reactive gases in the PECVD system (Plasma Enhanced Chemical Vapor Deposition) with the substrates/wafers to be coated and a plasma is generated between the substrate holding plates of the plasma boat by supplying a medium-frequency power. To do so, the plasma boat must be reliably contacted, which would definitely make conveyance in a continuous system difficult. The properties of the layer created can be influenced in a variety of ways by varying the temperature, pressure, frequency, mixing ratio of gases and electric power input. In this direct plasma technique, there is no loss of plasma-activated reactants on the path between the activation site and the deposition site.

The object of the present invention is to create a continuous vacuum system with a compact design and a high throughput for plasma-supported treatment of substrate by a direct plasma technique at a reduced pressure, which ensures simple, rapid and reliable handling of the substrates with a high capacity of the substrate carrier.

This object is achieved according to the invention by the fact that the device for conveying the substrates through the continuous system has at least one plasma boat in which the substrates are arranged on a base plate in a three-dimensional stack in at least one plane at a predetermined distance from one another with intermediate carriers in between, whereby at least the intermediate carriers are made of graphite and can be acted upon by an alternating voltage via electric connecting means.

One characteristic of the invention is that the third dimension is also used for assembling the plasma boats with substrates. In a continuous system, compact three-dimensional substrate carriers are used in which the substrates are arranged side by side and/or one above the other in one or more planes at a slight distance in a horizontal stack arrangement or upright in a vertical arrangement. The substrates are thus processed in the system and/or are run through the system in stacks, which greatly increases capacity.

The substrates may also be arranged in at least two rows side by side on the base plate and/or in any plane whereby the base area of the base plate and/or the intermediate plate is 1 m×0.2 m. Other dimensions may of course also be selected, depending on the local conditions and/or substrate sizes.

In another further embodiment of the invention, the distance provided between the substrates in the stack arrangement is between 3 and 20 mm.

In one variant of the invention, the substrates are fixedly attached on both sides to intermediate plates standing on the base plate in such a way that the two substrates always face one another. The attaching of the substrates may be accomplished here by three mushroom-shaped pins protruding out of the intermediate plate on both sides and arranged in a triangle such that the substrates are secured in space behind the mushroom-shaped pins.

In one special embodiment, at least two plasma boats are arranged side by side and/or one above the other to pass through the continuous oven in one conveyor line. To this end, the base plates are equipped with sliding blocks or, in the interest of low friction, with rollers.

In one special variant, the plasma boat is secured in a conveyor frame consisting of interconnected longitudinal and transverse struts, whereby the longitudinal struts of the conveyor frame are equipped with regular recesses and/or teeth on the underside and engage in the gearwheels for horizontal conveyance of the conveyor frame with the graphite boat mounted therein. In this variant, the conveyor frame, which is subject to a certain wear, may be replaced easily.

The conveyor frame surrounds the graphite boat in a form-fitting manner on the outside in such a way that the graphite boat can be placed on boat supports situated in the corner areas of the conveyor frame.

Finally, the boat supports are designed to be electrically insulated with respect to the conveyor frame.

To form a uniform plasma in the process chambers, in particular near the substrate, in a special embodiment of the invention, every second intermediate plate is passed through and contacted with a predefined point at the base of the plasma boat, forming a first antenna arrangement, and the intermediate plates situated in between are each passed through and contacted at another predefined point at the base of the boat in such a way as to form a second antenna arrangement and are connected via the electric connecting means to feeder lines for alternating voltage to form a plasma between the first and the second antenna arrangements.

The electric connecting means may be embodied in the form of male HF contact plugs, which alternately contact at least the intermediate plates.

The contact plugs are movable by means of an actuator drive into the contact position with the respective contact points at the base of the boat and back again.

Finally, it is possible to provide for the device for conveyance of the substrates to comprise a plurality of conveyor lines running parallel to one another through the continuous system for simultaneous parallel conveyance of multiple plasma boats, such that the conveyor lines extend like a channel through the continuous system.

The substrate carriers are expanded in height to increase the capacity according to the invention, i.e., the third dimension is utilized to increase capacity. The substrate carriers are thus designed so that they are suitable for especially efficient direct plasma PECVD technology in which reactive plasma burns in immediate proximity to the substrates. This system combines the advantages of a batch system with boats with those of a continuous system with flat substrate carriers.

By parallel processing of several compact substrate carriers, the plant size is scalable and the throughput can be adapted to the requirements of the manufacturing line.

By using compact substrate carriers, the throughput achievable in a single system is greater than that in traditional continuous systems.

The system concept allows a modular design both in the direction of material flow as well as transverse thereto. This allows an additional reduction in system and operating costs.

Even for very high throughputs that have not previously been achieved, simple loading and unloading by traditional methods is possible, ensuring a higher throughput with a more compact design so that the cost per unit of throughput remains constant. At the same time a simple loading with less substrate breakage is ensured because all resting positions for the substrates 11 are readily accessible.

The invention will now be explained in greater detail below with reference to one exemplary embodiment. In the respective drawings:

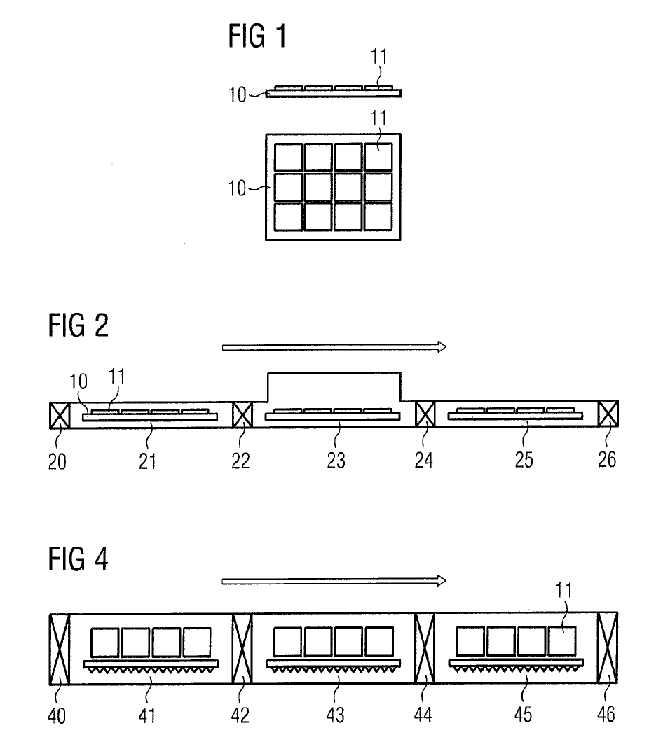

FIG. 1 shows schematic diagrams of a substrate carrier in various views with substrates lying flat according to the state of the art;

FIG. 2 shows a schematic diagram of a continuous system according to the state of the art;

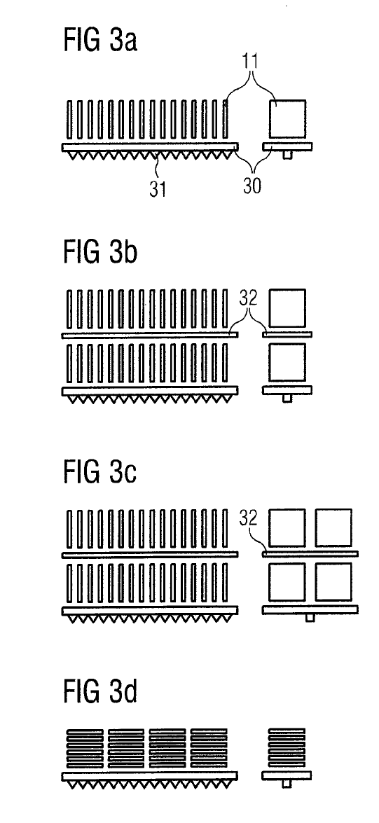

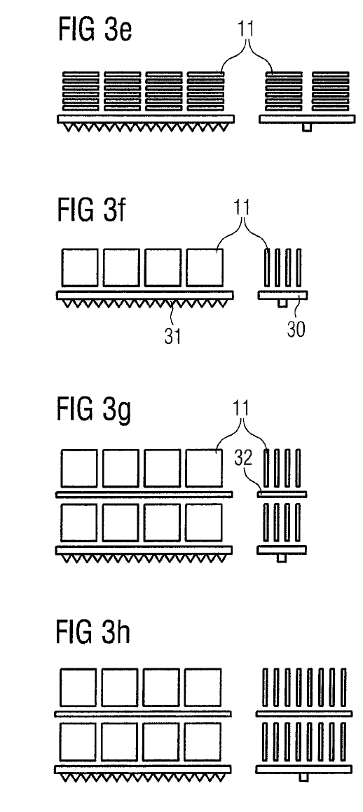

FIGS. 3a to h show schematic diagrams of inventive narrow substrate carriers with substrates stacked up in various ways utilizing the third dimension;

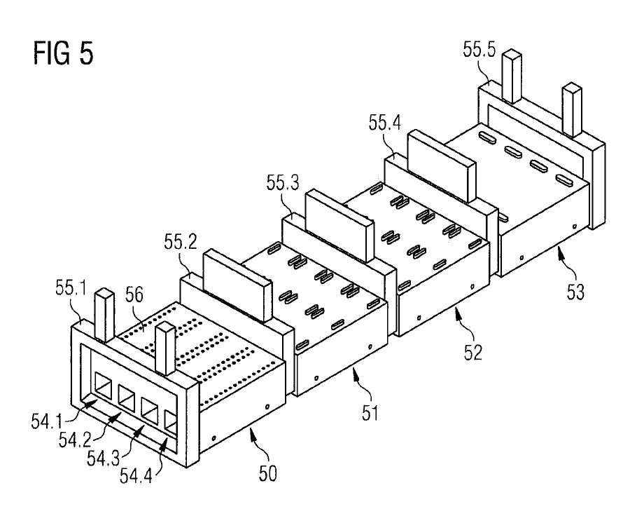

FIG. 4 shows a schematic diagram of an inventive continuous system;

FIG. 5 shows a perspective overview of a PECVD continuous system;

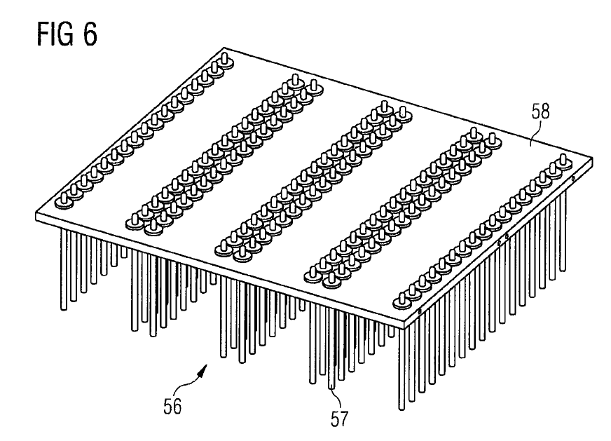

FIG. 6 shows a chamber cover having an integrated lamp field for a heating chamber;

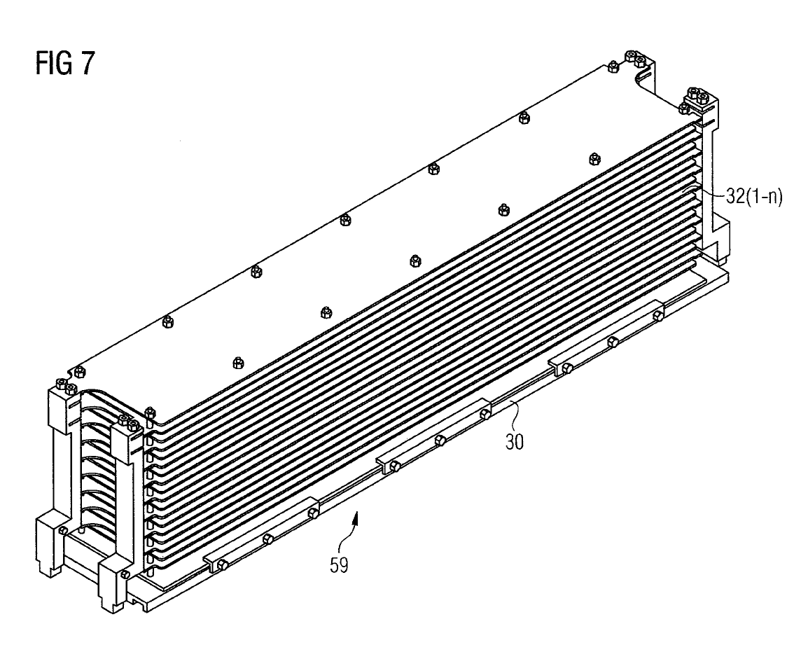

FIG. 7 shows a perspective diagram of an inventive boat for receiving six stacks of substrates in a horizontal arrangement;

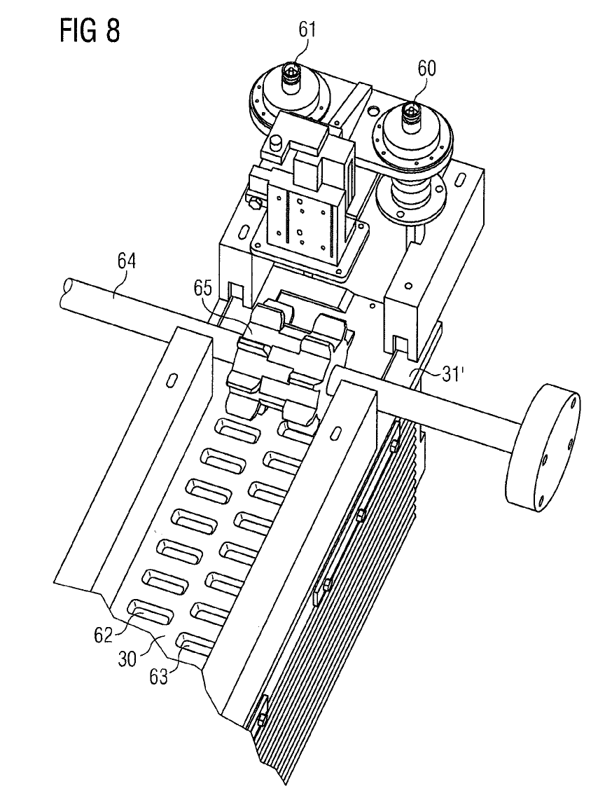

FIG. 8 shows a perspective sectional diagram of a detail of the boat according to FIG. 7 as seen from beneath with a drive device and plasma lances for electric coupling;

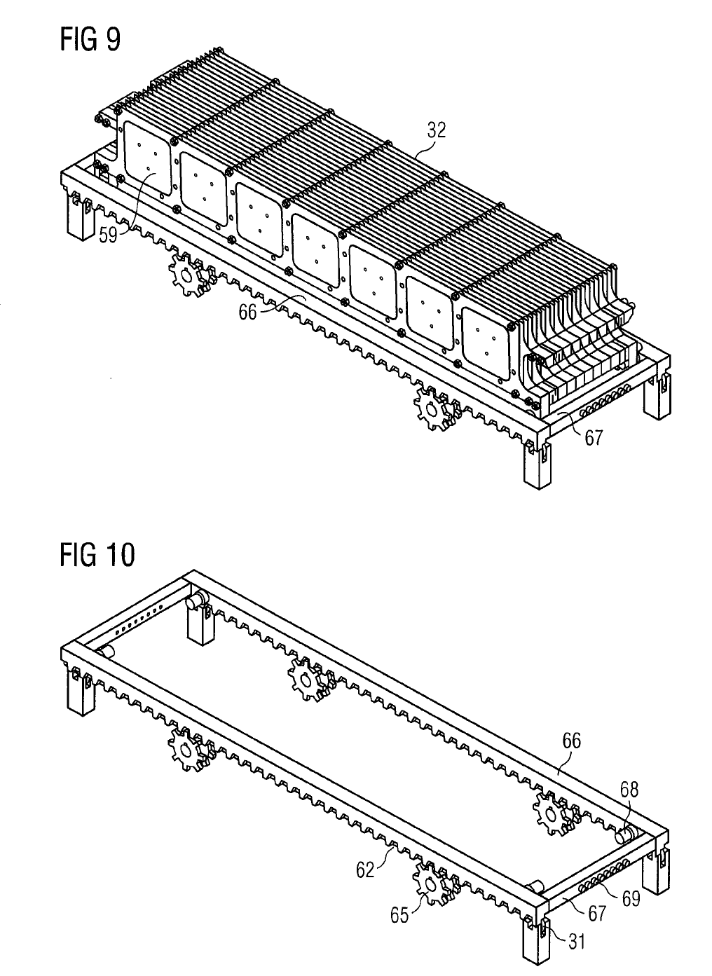

FIG. 9 shows a perspective diagram of a graphite plasma boat on a conveyor frame with vertically and/or upright arranged substrates and

FIG. 10 shows a perspective diagram of the conveyor frame according to FIG. 9 in which the plasma boat can be suspended.

The usual continuous systems according to the state of the art for treatment of substrates at a reduced pressure consists according to FIG. 2 in the simplest case of an input air lock 21, a process chamber 23 and an outlet air lock 25. The air locks and the process chamber are usually provided with vacuum-tight slide valves 20, 22, 24, 26, so that independent evacuation of the air locks and the process chamber is made possible. Flat/low/plate-shaped substrate carriers 10 (FIG. 1, state of the art) are used with flat rectangular substrates 11 situated on them in a plane, arranged in rows and columns. The substrate carrier usually rests on drive rollers for conveyance.

The passage of throughput of a substrate carrier through the continuous system according to FIG. 2 (state of the art) then takes place as described below, for example.

The inlet slide valve 20 is opened and the inlet air lock 21 is aerated, the process chamber 23 and the outlet air lock 25 are under a reduced pressure. The substrate carrier 10 is introduced into the inlet air lock 21, then the inlet slide valve 20 is closed and the inlet airlock 21 is evacuated. As soon as the same pressure as in the process chamber 23 has been reached, the second slide valve 22 is opened and the substrate carrier 10 is transferred into the process chamber 23. The second slide valve 22 is closed and the treatment of the substrates 11 may take place.

After conclusion of the treatment, the third slide valve 24 is opened and the substrate carrier 10 is transferred into the outlet air lock 25. Next the third slide valve 24 is closed and the outlet air lock 25 is aerated. Next the outlet slide valve 26 is opened and the substrate carrier 10 may then be removed from the system. The outlet slide valve 26 is closed again and the outlet air lock 25 may be evacuated again.

It is self-evident that such continuous systems according to the state of the art fulfill their assigned purpose only if multiple substrate carriers 10 are within the system at the same time. The sequence of the passage of the substrate carriers 10 through the system is more complex in this case than that described above.

The inventive substrate carrier, also known as a boat, which is represented schematically in FIGS. 3a-3h preferably consists of a base plate 30 of a conductive material, e.g., graphite, on which the substrates 11 are arranged in one or more planes at a slight distance (approximately 3 to 20 mm) in a horizontal arrangement (e.g., FIG. 3d) or in a vertical arrangement (e.g., FIG. 3a) side by side and/or one above the other, longitudinally or transverse to the direction of travel of the substrate carrier.

FIGS. 3b, 3g show the arrangement of substrates 11 in two planes, whereby the substrates 11 of the upper layer are arranged on an intermediate carrier 32 which is also made of a conductive material, e.g., graphite.

In FIG. 3c, two rows of substrates 11 are arranged in two planes, whereby the two upper rows are also on an intermediate carrier 32. FIG. 3h shows a variant according to FIG. 3c with a broadened base plate 30 and a broadened intermediate carrier 32 to accommodate two rows of substrates 11 on each.

The substrates 11 are each arranged across the direction of travel according to FIGS. 3a-3c and according to FIGS. 3f-3g they are standing upright and arranged along the direction of travel and according to Figures d, e [sic] they are arranged horizontally.

It is self-evident that each substrate 11 must be held securely on the face plate 30 or on the intermediate carrier 32 by means of a suitable holding device, such that the distance between substrates must not be less than a predefined minimum to allow adequate passage of gas.

Furthermore, in all embodiments of FIG. 3, additional intermediate carriers of a conductive material, e.g., graphite, must be arranged between the substrates 11; in combination with a suitable alternating voltage supply, these intermediate carriers act as electrodes and/or antennas as will be explained in greater detail below.

For conveyance, the base plate 30 may be equipped with sliding blocks 31′ (FIG. 8) or rollers 31, for example, which greatly reduces friction. In addition, the base plate 30 is equipped with contacts, which allow a low- or high-frequency alternating voltage power in the kW range to be supplied. To do so, extremely low transmission resistances between the contacts and the base plate are assured at all times.

Due to the three-dimensional stacked arrangement of the substrates 11 on the base plate in one or more levels, a very compact arrangement with a high capacity is created.

FIG. 4 shows a schematic diagram of one example of an inventive continuous system consisting of three chambers arranged in succession, namely a heating chamber 41, a downstream process chamber 43 and a cooling chamber 45. Vacuum slide valves 40 and/or 46 form the beginning and the end of the continuous system, with additional slide valves 42, 44 arranged between the heating chamber 41 and the process chamber 43, and between the process chamber 43 and the cooling chamber 45. If the process conditions in the different chambers do not vary greatly, the slide valves need not be vacuum-tight, and/or in this case the use of slide valves may optionally be omitted entirely.

The vacuum pumps and reactive gas and/or purging gas supply lines, which are needed for operation of this continuous system, are not shown.

With a usable dimension of the rectangular face plate of 1×0.2 m, for example, and an embodiment of the substrate carrier in 17 levels (FIG. 3c), this yields a capacity of the substrate carrier of approximately 96 substrates of the size 156×156 mm with a distance of 11 mm between the substrates. Because of their compactness, several substrate carriers can be processed in parallel, and because of this the plant throughput is not limited by the capacity of the substrate carriers.

In a two-dimensional plate system according to the state of the art, only six substrates could be accommodated in the same area.

The continuous system according to the invention is designed as a modular unit. The substrate carriers pass through individual stations in it, the functions of which, such as a evacuating, heating, preplasma for surface conditioning, coating, cooling and aerating, may be adapted to meet the demands of the process.

FIG. 5 shows an overview diagram of a continuous PECVD system consisting of a heating chamber 50, a downstream chamber for surface conditioning 51, a downstream coating chamber 52 and finally a cooling chamber 53, whereby conveyor lines 54 running in parallel pass through all the chambers 50, 51, 52, 53, each passing a vacuum slide valve 55.1-55.5 at the beginning and end of each chamber segment 50, 51, 52, 53. The chambers 51 and 52 are each plasma processing chambers.

Essentially there is also the possibility of combining the heating chamber 50 with the respective vacuum slide valve 55.1 at the input end and combining the cooling chamber 53 with the respective vacuum slide valve 55.5 at the output end to form a modular group.

The heating chamber 50 is equipped with an integrated lamp field 56 for each conveyor line 54 for rapid heating of the plasma boats equipped with the substrates 11 (FIGS. 5, 6). The lamps 57 assigned to the respective conveyor lines 54 are attached to the cover 58 of the heating chamber 50 in such a way that the boats 30 can be inserted between them.

It is also possible to design the entire continuous system as a cold wall reactor with integrated lamps, which ensures very rapid heating. This has the advantage that a longitudinal extending of the heated chambers 50, 51, 52, 53 is omitted.

It is self-evident that each of the chambers of the continuous PECVD system must be connected to a device for generating a vacuum in the form of vacuum pumps. In addition, the cooling chamber 53 may be connected to a purging gas supply line to remove the reaction gases completely before opening the vacuum side valve.

In addition, the chambers for surface conditioning 51 and the downstream coating chamber 52 are connected to supply lines for process gases and purging gases.

The chambers 50, 51, 52, 53 may each be opened for maintenance and cleaning purposes, whereby the seal on the chamber cover may be provided in the form of an O ring rubber seal.

Each process step may be distributed between successive stations if the material flow and cycle times require this.

Because of their compactness, several boats (base plates 30 optionally with intermediate carriers 32) may be processed in parallel. FIG. 7 shows a graphite boat 59 for holding the substrates 11 in a horizontal arrangement as diagrammed schematically in FIG. 3d.

The chambers 50, 51, 52, 53 are equipped for this with the corresponding number of conveyor lines 54.1, 54.2, 54.3, 54.4 and a respective drive system. This yields the particular feature of the invention whereby the plant throughput can be adapted to the requirements of the line as whole without any problems at all.

The plasma required for coating the substrates 11 is generated between the plates 32 that are located directly opposite one another and the substrates 11. To do so, the plates 32₍₁₋ₙ₎, which are located directly opposite one another, including the substrates 11 which are placed thereon or attached thereto, are acted upon by an alternating voltage of the opposite polarity, usually in kHz, e.g., at 40 kHz, or in MHz, e.g., at 13.5 MHz or 27 MHz (FIGS. 7, 8). Thus a so-called capacitive plasma develops directly above the surface of the substrates 11, mediated by the intermediate plates 32 functioning as electrodes. The substrate 11 itself thus becomes the plasma-generating electrode. In FIG. 7, a stack consists of n=17 substrates. A total of four such boats 30 may be processed side by side at the same time through the continuous system.

If the substrates 11 are arranged on the plasma boat 30 so they are upright, as indicated schematically in FIGS. 3a-c and 3f-h, the plasma burns between the substrates. With an upright arrangement of the substrates 11, they are attached fixedly on both sides to the intermediate plates 32 standing fixedly on the base plate 30 so that two substrates 11 are always opposite one another. The attachment of the substrates may be accomplished here easily by three mushroom-shaped pins arranged so they protrude out of the intermediate plate 32 on both sides and form a triangle on the surface of the intermediate plate 32. The substrates 11 are simply inserted here behind the mushroom-shaped pins so that the substrates are secured at three points each.

Depending on the composition of the process gas, the plasma may, for example, coat, clean, activate, oxidize, etc. the surface of the substrate 11 facing the plasma.

The supply of alternating voltage to the base plates 30 and the intermediate plates 32, i.e., contacting of the substrate carriers, takes place according to FIG. 8 in such a way that every second intermediate plate 32 is passed through to the front end of the boat in the direction of advance and is contacted, which thereby forms a first antenna arrangement and the intermediate plates in between are each passed through and contacted with the rear end of the boat, thereby forming a second antenna arrangement. When an alternating voltage with alternating polarity is applied, a plasma corresponding to the process gas that is supplied then develops between the first and second antenna arrangements, which are intermeshed more or less like combs. The prerequisite is of course a corresponding vacuum in the process chamber.

After the plasma boat has been introduced into the process chamber, e.g., the process chamber for surface conditioning 51 or the coating chamber 52, and correctly positioned there, the stationary plasma boat is contacted electrically.

To do so, two male HF contact plugs 60, 61, for example, which may also be referred to as plasma lances, are inserted upward from beneath, e.g., from front to rear on the plasma boat 30, into corresponding bushings (not shown) in the boat 30 by means of a suitable actuator drive (FIG. 8), so that the boat 30 is secured at the site at the same time.

The HF contact plugs 60, 61 establish the electric connection between the corresponding plates 32 of the plasma boat 30 and an alternating voltage supply. Under the assumption that one or more process gases are present in sufficient concentration within the process chamber, a plasma develops between the plates after the alternating voltage is turned on. After the process is concluded, the alternating voltage is turned off, the HF contact plugs 60, 61 are retracted and the boat 30 can be conveyed further to the next station.

Details of the conveyor device for the boats 30 in the individual chambers 50, 51, 52, 53 are shown in FIG. 8. The base plates 30 are provided with recesses 62, 63 arranged in two rows on the underside, with the teeth of a gearwheel 65 on a drive shaft 64 engaging in the recesses.

FIGS. 9 and 10 show another embodiment of the invention in which the substrates are arranged in vertical intermediate carriers 32 in the form of substrate carrier plates on a plasma boat 59 made of graphite.

The plasma boat 59 is secured in space in a conveyor frame according to FIG. 9 whereby the conveyor frame consists of interconnected longitudinal and transverse struts 66, 67. This conveyor frame is shown in detail in FIG. 10. The conveyor frame encloses an area, which is sufficient for the plasma boat 59 to be immersed into it so that the plasma boat 59 is surrounded by the conveyor frame in a form-fitting manner.

Within the border of the conveyor frame formed by the longitudinal and transverse struts 66, 67 there are boat supports 68, which are electrically insulated, in the corner areas, so that the plasma boat 59 is held securely by its own weight, as shown in FIG. 9, on insertion and in further conveyance horizontally through the continuous system as diagrammed schematically in FIG. 4. Electric contacting of the graphite boat 59 to generate the required plasma takes place in the arrangement according to FIG. 9, like that in FIG. 7, and/or as depicted in the corresponding description.

The necessary electric contact elements are shown at the right front end in FIG. 9.

FIGS. 9 and 10 also show that the two longitudinal struts 66 arranged parallel to one another are equipped on their underside with regularly distributed recesses 62 and/or teeth, which are comparable to a toothed rack, engage in the gearwheels 65 so that in combination with a corresponding drive, conveyance of the conveyor frame with the graphite boat 59 through a continuous system is made possible, as diagrammed schematically in FIG. 4. To prevent tipping of the conveyor frame during transport, rollers 31 or sliding rails on which the conveyor frame is guided horizontally and securely through the continuous system in combination with the gearwheels 65 are provided at intervals.

In addition, the conveyor frame is provided with coding pins 69 which may be inserted or removed as needed and allow detection of the graphite boat 59 with the help of a binary number by scanning according to a conventional method.

### LIST OF REFERENCE NUMERALS

10 Substrate carrier
11 Substrate
20 Slide valve
21 Inlet air lock
22 Slide valve
23 Process chamber
24 Slide valve
25 Outlet air lock
26 Slide valve
30 Base plate/plasma boat
31 Rollers
31′ Sliding rail
32 Intermediate carrier
40 Vacuum slide valve
41 Heating chamber
42 Vacuum slide valve
43 Process chamber
44 Vacuum slide valve
45 Cooling chamber
46 Vacuum slide valve
50 Heating chamber
51 Chamber for surface conditioning
52 Illumination chamber
53 Cooling chamber
54 Conveyor line
55 Vacuum slide valve 4
56 Lamp field
57 Lamp
58 Cover
59 Plasma boat
60 HF contact plug
61 HF contact plug
62 Recess
63 Recess
64 Drive shaft
65 Gearwheel
66 Longitudinal strut
67 Transverse strut
68 Boot support
69 Coding pin

1. A continuous vacuum system for processing substrates, comprising an inlet air lock and an outlet air lock and at least one process chamber, as well as a device for conveying the substrates through the continuous system, wherein the device for conveying the substrates through the continuous system has at least one plasma boat in which the substrates are arranged on a base plate in a three-dimensional stack in at least one plane at a predetermined distance from substrates of another plane with intermediate carriers in between planes, and wherein at least the intermediate carriers are made of an electrically conductive material to be acted upon electrically via electric connecting means with an alternating voltage.

2. The continuous vacuum system according to claim 1, wherein the substrates of a plane are arranged in a horizontal stack arrangement or in a vertical arrangement upright on the base plate of the plasma boat.

3. The continuous vacuum system according to claim 1, wherein substrates of each additional plane are each arranged on an intermediate carrier at a distance from the base plate of the plasma boat.

4. The continuous vacuum system according to claim 3, wherein the substrates are arranged in at least two planes.

5. The continuous vacuum system according to claim 1, wherein the substrates are arranged in at least two rows side by side on the base plate of the plasma boat.

6. The continuous vacuum system according to claim 1, wherein the substrates are arranged in at least two rows in each plane.

7. The continuous vacuum system according to claim 1, wherein a base area of the base plate of the plasma boat and/or of the intermediate plates is 1 m×0.2 m.

8. The continuous vacuum system according to claim 1, wherein the predetermined distance of the substrates from one another is approximately 3-20 mm.

9. The continuous vacuum system according to claim 1, wherein the substrates are attached on both sides to intermediate plates standing fixedly on the base plate of the plasma boat, such that two substrates are always opposite one another.

10. The continuous vacuum system according to claim 9, wherein for fastening the substrates three mushroom-shaped pins that protrude out of a surface of an intermediate plate on both sides and are arranged in a triangle are provided, whereby the substrates are secured spatially behind the mushroom-shaped pins.

11. The continuous vacuum system according to claim 1, wherein at least two plasma boats are run side by side and/or one above the other through the continuous system.

12. The continuous vacuum system according to claim 1, wherein the base plate of the plasma boat is equipped with sliding blocks.

13. The continuous vacuum system according to claim 1, wherein the base plate of the plasma boat is equipped with rollers.

14. The continuous vacuum system according to claim 1, wherein the plasma boat is secured in a conveyor frame, the conveyor frame is made of interconnected longitudinal and transverse struts, and the longitudinal struts of the conveyor frame are equipped with regular recesses and/or teeth on an underside, meshing in gearwheels for horizontal conveyance of the conveyor frame with the plasma boat situated therein.

15. The continuous vacuum system according to claim 14, wherein the conveyor frame surrounds the plasma boat in a form-fitting manner on an outside such that the plasma boat can be placed onto boat supports provided in corner areas of the conveyor frame.

16. The continuous vacuum system according to claim 15, wherein the boat supports are electrically insulated with respect to the conveyor frame.

17. The continuous vacuum system according to claim 1, wherein every second intermediate plate is passed through and contacted with a base point of the boat, forming a first antenna arrangement, and the intermediate plates in between are each passed through and contacted with a second base point of the boat, forming a second antenna arrangement, and are connected via the electric connecting means to supply lines for alternating voltage to form a plasma between the first and second antenna arrangements.

18. The continuous vacuum system according to claim 1, wherein the electric connection means comprise male HF contact plugs which contact at least the intermediate plates via current distribution busbars.

19. The continuous vacuum system according to claim 18, wherein the HF contact plugs are movable by an actuator drive.

20. The continuous vacuum system according to claim 1, wherein the device for conveying the substrates through the continuous system comprises a plurality of parallel conveyor lines for simultaneous parallel conveyance of multiple plasma boats.

21. The continuous vacuum system according to claim 20, wherein the conveyor lines extend in the form of a channel through the continuous system.
